(19) United States
(12) Patent Application Publication
(10) Pub. No.: US 2016/0043116 A1
(43) Pub. Date: Feb. 11, 2016

(54) THIN FILM TRANSISTOR AND MANUFACTURING METHOD THEREOF, ARRAY SUBSTRATE AND MANUFACTURING METHOD THEREOF AND DISPLAY DEVICE

(71) Applicant: BOE TECHNOLOGY GROUP CO., LTD., Beijing (CN)

(72) Inventors: Hongda SUN, Beijing (CN); Jun CHENG, Beijing (CN); Meili WANG, Beijing (CN); Xiangyong KONG, Beijing (CN)

(21) Appl. No.: 14/429,168

(22) PCT Filed: Jul. 25, 2014
(86) PCT No.: PCT/CN2014/083000

§ 371 Date: Mar. 18, 2015

(30) Foreign Application Priority Data
Sep. 30, 2013 (CN) 201310461867.2

(51) Int. Cl. H01L 27/12; H01L 29/24; H01L 29/423; H01L 29/417; H01L 29/786; H01L 29/66

(52) U.S. Cl. CPC H01L 27/1288; H01L 29/7869; H01L 29/66969; H01L 29/42384; H01L 29/41733; H01L 27/1225; H01L 29/24; H01L 27/124; H01L 29/78669; H01L 29/66765; H01L 27/1222

(57) ABSTRACT

The present invention discloses a thin film transistor and a manufacturing method thereof, an array substrate and a manufacturing method thereof and a display device. The thin film transistor comprises a substrate, and a gate, an active layer, a source, a drain and an insulation layer which are provided on the substrate, the source and the drain are provided in the same layer, and the insulation layer is provided between the gate and the source and drain. A gate preformed layer is provided in the same layer as the gate, and the gate is formed in the gate preformed layer. A source/drain preformed layer is provided in the same layer as the source and the drain, and the source and the drain are formed in the source/drain preformed layer.

### FIELD OF THE INVENTION

The present invention belongs to the field of display technology, and in particular relates to a thin film transistor and a manufacturing method thereof, an array substrate and a manufacturing method thereof and a display device.

### BACKGROUND OF THE INVENTION

With the development of science and technology, flat panel display devices have substituted heavy CRT (Cathode Ray Tube) display devices and are increasingly common in people's daily lives. At present, common flat panel display devices include LCD (Liquid Crystal Display) and OLED (Organic Light-Emitting Diode) display devices.

In the imaging process, both LCD and active matrix OLED (Active Matrix Organic Light Emission Display, referred to as AMOLED) display devices comprise thin film transistors (referred to as TFT) formed in an array substrate. The thin film transistors are the key of realizing displaying of the LCD and the active matrix OLED display devices, and are directly relevant to the development direction of high-performance display devices.

As shown in FIG. 1, a typical structure of a thin film transistor comprises a substrate 1, and a gate 2, a gate insulation layer 4, an active layer 5, an etch stop layer 6 which are formed on the substrate 1, and a source 7 and a drain 8 formed above the etch stop layer 6. At present, the process for manufacturing the thin film transistor is generally a patterning process, and patterns comprising each film layer are sequentially fabricated from bottom to top. The thin film transistor has many film layers, so in the process of forming each film layer by adopting the patterning process, e.g., in depositing and etching steps, a tiny convex or concave defect or flaw 15 (of course, it may also be a flaw of concavity of the whole layer) is easily formed at the sudden change position of a pattern due to a certain preformed film layer, e.g. at the slope shown in FIG. 1 due to irregular etching. In FIG. 1, a concavity is formed in the gate insulation layer 4 due to over-etching. If the concavity is too deep or too large, the flaw of concavity will not be filled, with the proceeding of coating of films, because material is difficult to be deposited on the portions below blocking portions during deposition of subsequent film layers. Moreover, the deposited film layer is easily etched off by a partial over-etching during etching process, thus an increasingly serious flaw is formed, as a result, the film layers which should not be connected with each other are finally in contact with each other, e.g. the active layer 5 may be discontinuous in the area corresponding to the flaw in FIG. 1, then the insulation between the source 7 and the gate 2 may be destroyed, and the source 7 may be connected with the gate 2. It could be inferred that, once a certain film layer is convex or concave at the sudden change position of a pattern, the discontinuous situation caused by the convex or concave situation of subsequent film layers will be further aggravated with the accumulation of multiple patterning processes, which will result in the problem of poor performance of a display panel, particularly result in connection between metal electrodes due to the concave situation, and electric leakage of the display panel is finally caused. Once the display panel leaks electricity, the whole display panel is disabled, so that the production cost is greatly wasted.

Thus, currently, a problem to be urgently solved in the art is to design such a thin film transistor, in which the problem that insulation between film layers is destroyed due to the influence of manufacturing process will not occur, and electric leakage between metal electrodes may be effectively avoided, and therefore the product quality is improved.

### SUMMARY OF THE INVENTION

With respect to the above shortcomings in the prior art, the technical problem to be solved by the present invention is to provide a thin film transistor and a manufacturing method thereof, an array substrate and a manufacturing method thereof and a display device. In the thin film transistor and the corresponding array substrate, negative effects caused by etched flaws of a gate or a source and a drain at the slope may be effectively reduced, the probability that a subsequent film layer is discontinuous may be avoided, and the quality of the display device may be improved.

According to an aspect of the present invention, there is provided a thin film transistor, comprising a substrate, and a gate, an active layer, a source, a drain and an insulation layer which are provided on the substrate, the source and the drain are provided in the same layer, and the insulation layer is provided between the gate and the source and drain; a gate preformed layer is provided in the same layer as the gate, and the gate is formed in the gate preformed layer; and/or a source/drain preformed layer is provided in the same layer as the source and the drain, and the source and the drain are formed in the source/drain preformed layer.

In the thin film transistor, e.g. the gate is provided on the substrate, and the source and the drain are provided above the gate; a gate embedded groove is formed in a region, for forming the gate, of the gate preformed layer, and the gate is provided in the gate embedded groove; and/or a source embedded groove is formed in a region, for forming the source, of the source/drain preformed layer, a drain embedded groove is formed in a region, for forming the drain, of the source/drain preformed layer, the source is provided in the source embedded groove, and the drain is provided in the drain embedded groove.

In the thin film transistor, e.g. the source and the drain are provided on the substrate, and the gate is provided above the source and the drain; a source embedded groove is formed in a region, for forming the source, of the source/drain preformed layer, a drain embedded groove is formed in a region, for forming the drain, of the source/drain preformed layer, the source is provided in the source embedded groove, and the drain is provided in the drain embedded groove; and/or a gate embedded groove is formed in a region, for forming the gate, of the gate preformed layer, and the gate is provided in the gate embedded groove.

Both of the gate preformed layer and the source/drain preformed layer may be made of inorganic material, and the inorganic material includes silicon nitride, silicon oxide or silicon oxynitride.

The gate may have a thickness the same as the gate preformed layer, and the source and the drain may have thicknesses the same as the source/drain preformed layer.

In the thin film transistor, the active layer is provided between the insulation layer and the source and drain, the active layer is at least partially superposed with the source and the drain, respectively, in the positive projection direction; and the active layer is made of amorphous silicon material, or is made of indium gallium zinc oxide, indium zinc oxide, indium tin oxide or indium gallium tin oxide.

According to another aspect of the present invention, there is provided an array substrate, comprising gate lines, data lines and thin film transistors provided in pixel areas formed by the gate lines and the data lines intersecting with each other in different planes, wherein the thin film transistors are the above-mentioned thin film transistors.

In the array substrate, the gate preformed layer also extends to regions of the pixel areas other than the regions corresponding to the thin film transistors, and the gate lines are provided in the same layer as the gates and electrically connected with the gates; and/or the source/drain preformed layer also extends to regions of the pixel areas other than the regions corresponding to the thin film transistors, and the data lines are provided in the same layer as the sources and electrically connected with the sources.

Gate line embedded grooves are formed in areas, for forming the gate lines, of the gate preformed layer, and the gate lines are provided in the gate line embedded grooves; and/or data line embedded grooves are formed in areas, for forming the data lines, of the source/drain preformed layer, and the data lines are provided in the data line embedded grooves.

The gate line may have a thickness the same as the gate, and the data line may have a thickness the same as the source.

According to a further aspect of the present invention, there is provided a display device, comprising the above-mentioned array substrate.

According to a still further aspect of the present invention, there is provided a manufacturing method of a thin film transistor, comprising steps of: forming a gate, an active layer, a source, a drain and a gate insulation layer on a substrate, the gate insulation layer is provided between the gate and the source and drain; the method further comprises steps of forming a gate preformed layer in the same layer as the gate, and forming the gate in the gate preformed layer; and/or forming a source/drain preformed layer in the same layer as the source and the drain, and forming the source and the drain in the source/drain preformed layer.

In the manufacturing method, before the gate is formed, a pattern comprising the gate preformed layer and a gate embedded groove provided in the gate preformed layer is first formed; then a pattern comprising the gate is formed in the gate embedded groove; and/or, before the source and the drain are formed, a pattern comprising the source/drain preformed layer as well as a source embedded groove and a drain embedded groove provided in the source/drain preformed layer is first formed; then a pattern comprising the source is formed in the source embedded groove, and a pattern comprising the drain is formed in the drain embedded groove.

In the manufacturing method, a pattern comprising the gate preformed layer and the gate may be formed by a patterning process, and the gate preformed layer and the gate may be formed by adopting the same mask; or, a pattern comprising the gate preformed layer may be formed by a patterning process, and the gate may be formed in the gate embedded groove of the gate preformed layer by a melt perfusion manner; and/or a pattern comprising the source/drain preformed layer as well as the source and the drain may be formed by a patterning process, and the source/drain preformed layer as well as the source and the drain may be formed by adopting the same mask; or, a pattern comprising the source/drain preformed layer may be formed by a patterning process, and the source and the drain may be respectively formed in the source embedded groove and the drain embedded groove of the source/drain preformed layer by a melt perfusion manner.

The gate preformed layer and the source/drain preformed layer may be made of inorganic material, which includes silicon nitride, silicon oxide or silicon oxynitride.

The gate may have a thickness the same as the gate preformed layer, and the source and the drain may have thicknesses the same as the source/drain preformed layer.

According to a still further aspect of the present invention, there is provided a manufacturing method of an array substrate, comprising steps of forming gate lines, data lines and thin film transistors provided in pixel areas formed by the gate lines and the data lines intersecting with each other in different planes, wherein the thin film transistors are formed by the above-mentioned manufacturing method of the thin film transistor.

In the manufacturing method, the gate preformed layer extends to regions of the pixel areas other than the regions corresponding to the thin film transistors, so that the gate lines are formed in the same layer as the gates and electrically connected with the gates; and/or the source/drain preformed layer also extends to regions of the pixel areas other than the regions corresponding to the thin film transistors, so that the data lines are formed in the same layer as the sources and electrically connected with the sources.

In the manufacturing method, gate line embedded grooves are formed in areas, for forming the gate lines, of the gate preformed layer, and the gate lines are formed in the gate line embedded grooves; and/or data line embedded grooves are formed in areas, for forming the data lines, of the source/drain preformed layer, and the data lines are formed in the data line embedded grooves.

The gate line may have a thickness the same as the gate, and the data line may have a thickness the same as the source.

In the thin film transistor of the present invention, inorganic material is formed on the substrate, and a groove corresponding to a gate pattern is formed through exposure, development and etching; then a gate is formed, and the thickness of the gate is consistent with the depth of the groove, so that a complete pattern where gate metal material is filled into the groove; next, other film layers of the thin film transistor are formed; and/or the source and the drain have a structure similar to the gate. This structure may effectively reduce the negative effects caused by etched defects or flaws of the gate or the source and the drain at the slope, effectively solve the technical problem that unexpected flaws occur in the gate metal layer film or the source/drain metal layer film during depositing and etching, fundamentally avoid the probability of discontinuous situation caused by a convex or concave subsequent layer in the thin film transistor and improve the quality of the display device.

### BRIEF DESCRIPTION OF THE DRAWINGS

FIG. 1 is a cross sectional view of a thin film transistor in the prior art.

FIG. 2 is a cross sectional view of a structure of a thin film transistor in a first embodiment of the present invention.

FIG. 3 is a cross sectional view of a structure of a thin film transistor in the first embodiment of the present invention.

FIG. 4 is a cross sectional view of a structure a thin film transistor in the first embodiment of the present invention.

FIGS. 5A through 5H are cross sectional views of a process of forming a pattern comprising a gate in the thin film transistor of FIG. 4.

FIG. 6 is a structural schematic diagram illustrating that a convex flaw is produced at the gate in the first embodiment of the present invention.

FIG. 7 is a structural schematic diagram illustrating that a concave flaw is produced at the gate in the first embodiment of the present invention.

FIG. 8 is a cross sectional view of a structure of a thin film transistor in a second embodiment of the present invention.

FIG. 9 is a cross sectional view of a structure of an array substrate in a third embodiment of the present invention.

### DESCRIPTION OF THE PREFERRED EMBODIMENT

To make those skilled in the art better understand the technical solutions of the present invention, a thin film transistor and a manufacturing method thereof, an array substrate and a manufacturing method thereof and a display device will be further described in detail below in combination with the accompanying drawings and specific implementations.

### First Embodiment

This embodiment provides a thin film transistor, comprising a substrate, and a gate, a source, a drain and an insulation layer provided on the substrate, the source and the drain are provided in the same layer and the insulation layer is provided between the gate and the source and drain. In the thin film transistor, a gate preformed layer may be provided in the same layer as the gate, and the gate is formed in the gate preformed layer. Moreover, a source/drain preformed layer may be provided in the same layer as the source and the drain, and the source and the drain are formed in the source/drain preformed layer.

In this embodiment, the thin film transistor has a bottom-gate structure, namely the gate is provided on the substrate, and the source and the drain are provided above the gate. Specifically, the gate, a gate insulation layer, an active layer, the source and the drain are sequentially provided on the substrate. The active layer is at least partially superposed with the source and the drain, respectively, in the positive projection direction. According to different specific forming processes of the gate, the source and the drain, the thin film transistor in this embodiment may specifically include the following three structures.

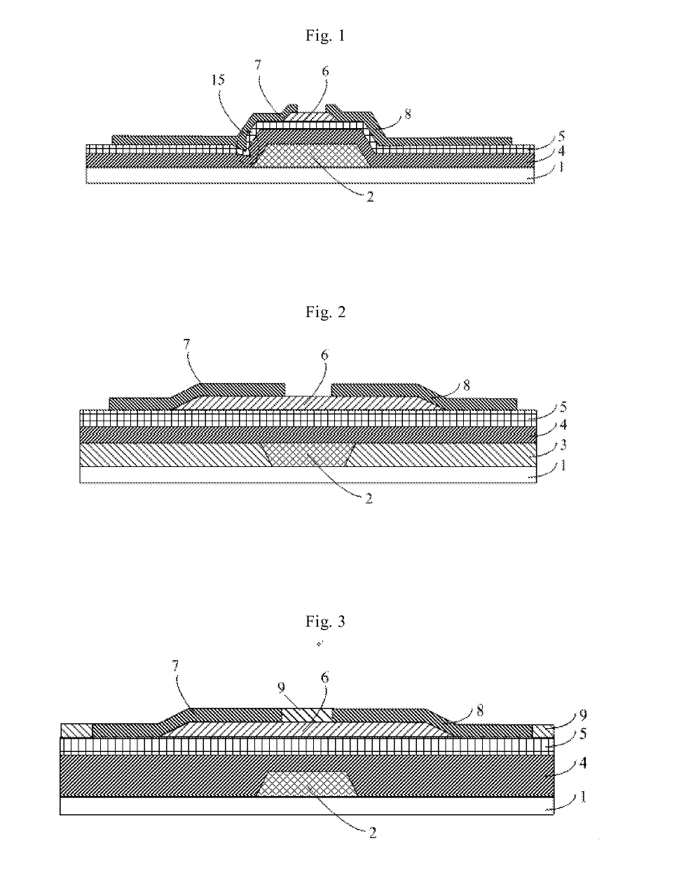

As shown in FIG. 2, in the thin film transistor, the gate 2 is provided on the substrate 1, and a gate embedded groove is formed in a region, for forming the gate 2, of the gate preformed layer 3. The gate 2 is provided in the gate embedded groove, and the gate insulation layer 4, the active layer 5, the source 7 and the drain 8 are sequentially provided above the gate 2.

As shown in FIG. 3, in the thin film transistor, the gate 2, the gate insulation layer 4 and the active layer 5 are sequentially provided on the substrate 1, a source embedded groove is formed in a region, for forming the source 7, of the source/drain preformed layer 9, and a drain embedded groove is formed in a region, for forming the drain 8, of the source/drain preformed layer 9. The source 7 is provided in the source embedded groove, and the drain 8 is provided in the drain embedded groove.

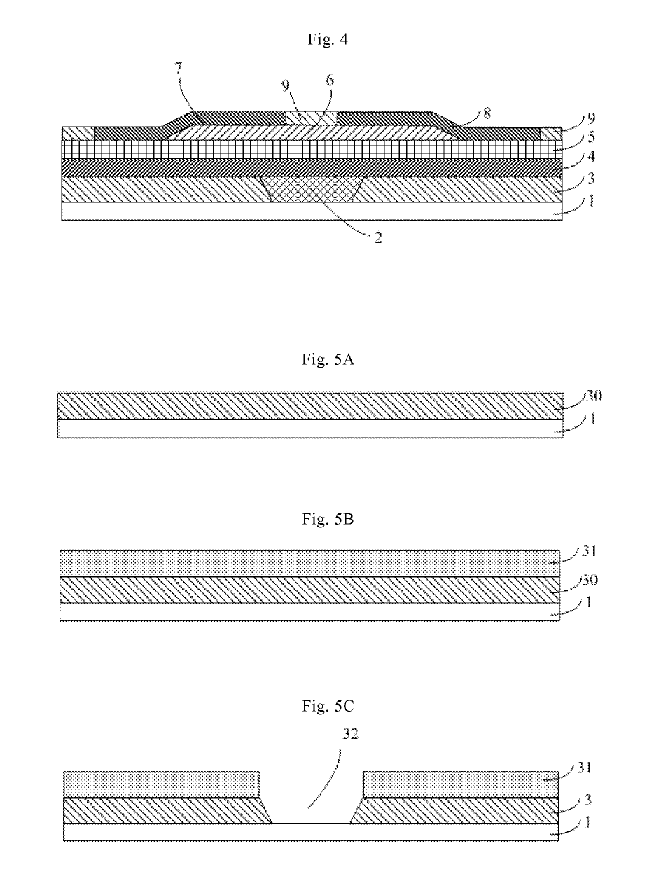

Alternatively, as shown in FIG. 4, in the thin film transistor, the gate 2 is provided on the substrate 1, a gate embedded groove is formed in a region, for forming the gate 2, of the gate preformed layer 3, and the gate 2 is provided in the gate embedded groove. The gate insulation layer 4 and the active layer 5 are provided above the gate 2, a source embedded groove is formed in a region, for forming the source 7, of the source/drain preformed layer 9, and a drain embedded groove is formed in a region, for forming the drain 8, of the source/drain preformed layer 9. The source 7 is provided in the source embedded groove, and the drain 8 is provided in the drain embedded groove.

In the structures of thin film transistor as shown in FIGS. 2 to 4, the gate preformed layer 3 and the source/drain preformed layer 9 are both made of inorganic material, which includes silicon nitride, silicon oxide or silicon oxynitride. The gate 2 may have a thickness the same as that of the gate preformed layer 3, and the source 7 and the drain 8 may have thicknesses the same as that of the source/drain preformed layer 9.

In this embodiment, the gate 2 may be made of molybdenum, molybdenum-niobium alloy, aluminum, aluminum-neodymium alloy, titanium or copper. The gate insulation layer 4 is of a single layer, double layers or multiple layers, and is made of silicon oxide, silicon nitride, hafnium oxide, silicon oxynitride or aluminum oxide. To ensure well contact between the active layer 5 and the source 7 and between the active layer 5 and the drain 8, an ohmic contact layer is further provided between the active layer 5 and the source 7 and drain 8. The active layer 5 is made of amorphous silicon material, the ohmic contact layer is made of amorphous silicon material doped with phosphorus element, and the electron mobility between the source 7 and the drain 8 is relatively low. Alternatively, to ensure that the active layer 5 is not destroyed when the source 7 and the drain 8 are formed, an etch stop layer 6 is further provided above the active layer 5. The active layer 5 is made of metal oxide semiconductor, e.g. indium gallium zinc oxide, indium zinc oxide, indium tin oxide or indium gallium tin oxide, so that the electron mobility between the source 7 and the drain 8 is improved, and high electron mobility between the source 7 and the drain 8 can be obtained. The etch stop layer 6 is made of silicon oxide, silicon nitride, hafnium oxide or aluminum oxide. The source 7 and the drain 8 are both made of molybdenum, molybdenum-niobium alloy, aluminum, aluminum-neodymium alloy, titanium or copper.

Accordingly, a manufacturing method of the above-mentioned thin film transistor comprises steps of forming a gate 2 on a substrate 1, forming a source 7 and a drain 8, and forming a gate insulation layer 4 between the gate 2 and the source 7 and drain 8. The manufacturing method further comprises steps of forming a gate preformed layer 3 in the same layer as the gate 2, and forming the gate 2 in the gate preformed layer 3. Moreover, the manufacturing method may comprises steps of forming a source/drain preformed layer 9 in the same layer as the source 7 and the drain 8, and forming the source 7 and the drain 8 in the source/drain preformed layer 9.

In brief, referring to FIG. 2, before the gate 2 is formed, a pattern comprising the gate preformed layer 3 and the gate embedded groove provided in the gate preformed layer 3 is first formed; and then a pattern comprising the gate 2 is formed in the gate embedded groove. Alternatively, referring to FIG. 3, before the source 7 and the drain 8 are formed, a pattern comprising the source/drain preformed layer 9 as well as the source embedded groove and the drain embedded groove provided in the source/drain preformed layer 9 is first formed; then a pattern comprising the source 7 is formed in the source embedded groove, and a pattern comprising the drain 8 is formed in the drain embedded groove. Alternatively, referring to FIG. 4, before the gate 2 is formed, a pattern comprising the gate preformed layer 3 and the gate embedded groove provided in the gate preformed layer 3 is first formed; and then a pattern comprising the gate 2 is formed in the gate embedded groove; moreover, before the source 7 and the drain 8 are formed, a pattern comprising the source/drain preformed layer 9 as well as the source embedded groove and the drain embedded groove provided in the source/drain preformed layer 9 is first formed; and then a pattern comprising the source 7 is formed in the source embedded groove, and a pattern comprising the drain 8 is formed in the drain embedded groove.

The thin film transistor of the present invention is formed by patterning processes. The patterning process of the present invention may only include a photolithographic process, or include the photolithographic process and an etching step, or may further include other processes such as printing, ink jet and the like for forming predetermined patterns. The photolithographic process refers to a process of forming a pattern through film forming (or coating), exposure, development and the like by adopting photoresist, mask plate, exposure machine and the like. The corresponding patterning process may be selected according to the structure to be formed in the present invention.

In this embodiment, a pattern comprising the gate preformed layer and the gate is formed by a patterning process, and the gate preformed layer and the gate are formed by adopting the same mask; and alternatively, a pattern comprising the gate preformed layer is formed by a patterning process, and the gate is formed in the gate preformed layer by a melt perfusion method. Similarly, a pattern comprising the source/drain preformed layer as well as the source and the drain is formed by a patterning process, and the source/drain preformed layer as well as the source and the drain are formed by adopting the same mask; and alternatively, a pattern comprising the source/drain preformed layer is formed by a patterning process, and the source and the drain are formed in the source/drain preformed layer by a melt perfusion method.

The manufacturing method of the thin film transistor as shown in FIG. 4 specifically comprises following steps S1 to S4.

Step S1, forming a pattern comprising a gate 2 on a substrate 1.

This step specifically comprises following sub-steps S11 to S18.

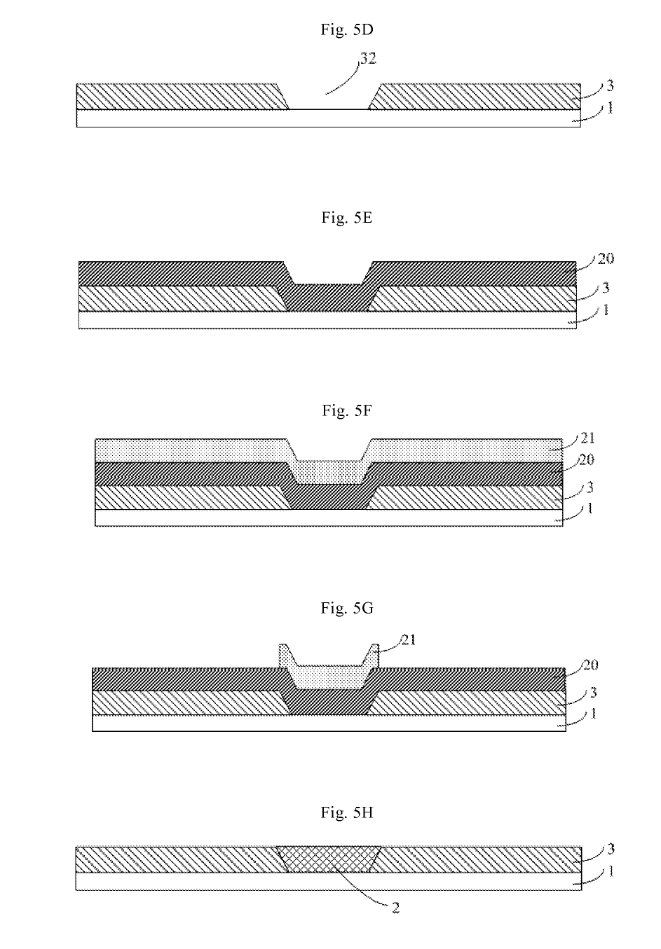

Step S11, forming a gate preformed layer film 30 first, as shown in FIG. 5A.

Step S12, forming a first photoresist layer 31 above the gate preformed layer film 30, as shown in FIG. 5B.

Step S13, forming a pattern comprising a gate preformed layer 3 and a gate embedded groove 32 provided in the gate preformed layer in the gate preformed layer film 30 through a first exposure and development process, as shown in FIG. 5C.

Step S14, removing the first photoresist layer 31, as shown in FIG. 5D.

Step S15, forming a gate metal layer film 20 above the gate preformed layer 3 and the gate embedded groove 32, as shown in FIG. 5E.

Step S16, forming a second photoresist layer 21 above the gate metal layer film 20, as shown in FIG. 5F.

Step S17, reserving a part of the second photoresist layer 21 corresponding to the gate embedded groove 32 through a second exposure and development process, and removing other parts of the second photoresist layer 21, as shown in FIG. 5G.

Step S18, reserving a part of the gate metal layer film 20 corresponding to the gate embedded groove 32 through an etching process, removing other parts of the gate metal layer film 20, also removing the second photoresist layer 21, thus forming a pattern comprising the gate 2, as shown in FIG. 5H.

In this step, the gate preformed layer film 30 or the gate metal layer film 20 is formed by a method of deposition, sputtering or thermal evaporation. The gate preformed layer film 30 is made of inorganic material, which includes silicon nitride, silicon oxide or silicon oxynitride, and the gate 2 has a thickness the same as the gate preformed layer 3.

In this step, the same mask is adopted for exposure in the patterning processes of the gate preformed layer 3 and the gate 2. Meanwhile, to ensure the accuracy of patterns in the exposure process, the exposure property of the photoresist in the first photoresist layer 31 is preferably opposite to that of the photoresist in the second photoresist layer 21. For example, the photoresist in the first photoresist layer 31 is negative photoresist, and the photoresist in the second photoresist layer 21 is positive photoresist.

A patterning process is adopted in the above-mentioned step of forming the pattern comprising the gate preformed layer and the gate. Alternatively, after the gate preformed layer 3 is formed, the gate 2 is formed in the gate embedded groove 32 by a melt perfusion manner (namely gate metal material is melted and then perfused into the corresponding groove), then steps S15 to S18 may be accordingly omitted, and the gate 2 formed in such a manner may be thinner and flatter.

Step S2, forming a pattern comprising a gate insulation layer 4 on the gate 2.

In this step, the gate insulation layer 4 is formed on the substrate 1 subjected to the step S1. The gate insulation layer 4 may be formed by a plasma enhanced chemical vapor deposition method.

Step S3, forming a pattern comprising an active layer 5 on the gate insulation layer 4.

In this step, a composite layer film is formed on the substrate 1 subjected to the step S2, the composite layer film may be formed by a method of deposition, sputtering, thermal evaporation or the like, the composite layer film comprises an active layer film and an etch stop layer film provided above the active layer film (which are sequentially deposited in the deposition process), and a pattern comprising a composite layer may be formed on the gate insulation layer 4 by using a common mask through one patterning process.

Alternatively, a pattern comprising a composite layer is formed on the substrate subjected to the step S2, the composite layer comprises an active layer and an ohmic contact layer provided above the active layer (which are sequentially deposited in the deposition process), and the pattern comprising the composite layer may be formed on the gate insulation layer 4 by using a common mask through one patterning process.

Step S4, forming a pattern comprising a source 7 and a drain 8 above the active layer 5.

This step specifically comprises following sub-steps S41 to S48.

Step S41, forming a source/drain preformed layer film.

Step S42, forming a first photoresist layer above the source/drain preformed layer film.

Step S43, forming a pattern comprising a source/drain preformed layer as well as a source embedded groove and a drain embedded groove provided in the source/drain preformed layer in the source/drain preformed layer film through a first exposure and development process.

Step S44, removing the first photoresist layer.

Step S45, forming a source/drain metal layer film above the source/drain preformed layer, the source embedded groove and the drain embedded groove.

Step S46, forming a second photoresist layer above the source/drain metal layer film.

Step S47, reserving a part of the source/drain metal layer film corresponding to the source embedded groove and the drain embedded groove through a second exposure and development process, removing other parts of the source/drain metal layer film, thus forming the pattern comprising the source and the drain.

Step S48, removing the second photoresist layer.

For each specific sub-step in this step, reference may be made to the cross sectional views of processes of forming the pattern comprising the gate in FIGS. 5A through 5H, and the corresponding accompanying drawings are omitted herein.

In this step, the source/drain preformed layer film or the source/drain metal layer film is formed by a method of deposition, sputtering or thermal evaporation. The source/drain preformed layer film is made of inorganic material, and the inorganic material includes silicon nitride, silicon oxide or silicon oxynitride. The source 7 and the drain 8 have thicknesses the same as that of the source/drain preformed layer 9. Moreover, the exposure property of the photoresist in the first photoresist layer is opposite to that of the photoresist in the second photoresist layer.

Similarly, after the source/drain preformed layer 9 is formed, the source 7 and the drain 8 may be formed in the source embedded groove and the drain embedded groove by a melt perfusion manner, then steps S45 to S48 may be accordingly omitted, and the source 7 and the drain 8 formed in such a manner may be thinner and flatter.

So far, manufacturing of the thin film transistor is completed.

For the manufacturing method of the thin film transistors in FIG. 2 and FIG. 3, reference may be made to specific steps (FIGS. 5A to 5H) of the manufacturing method of the thin film transistor in FIG. 4, which are not repeated herein.

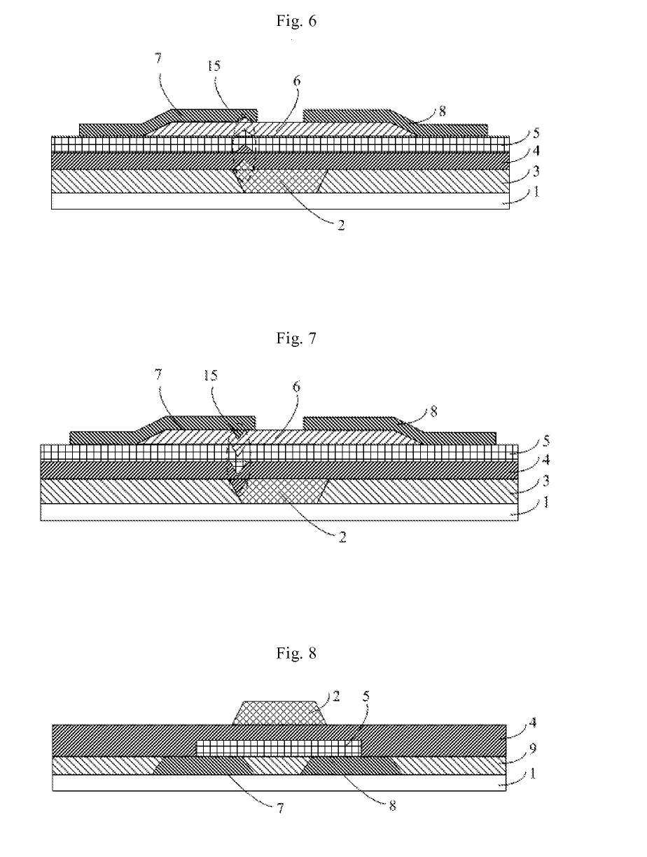

In this embodiment, before the gate is formed on the substrate, the gate preformed layer is formed first, and the gate embedded groove required for accommodating and fixing the gate is formed through exposure, development and etching; and the gate with the thickness the same as that of the gate preformed layer is formed, thus the gate completely filled into the gate embedded groove is obtained. Under such a condition, in the process of forming the pattern of the gate, even after the etching step is ended, the situation that the surface of the gate is uneven or a defect or flaw exists at the sudden change position of the pattern may still exist, but the flaw will not be aggravated during the formation of the subsequent film layers. For example, as shown in FIG. 6, when the over-etching quantity is relatively little or the pattern of the mask covers relatively large area during exposure, some protrusion (flaw 15) may be generated at the etched edge, the height of the protrusion is further smaller than the thickness of the gate, the protrusion is gradually reduced along with the formation of the subsequent film layers in the thin film transistor, and since the protrusion is not at the edge of other layers, the probability of electric leakage is not produced owing to the protrusion. As shown in FIG. 7, when the over-etching quantity is relatively large or the pattern of the mask covers relatively small area during exposure, some concavity (flaw 15) may be generated at the etched edge, the depth of the concavity is further smaller than the thickness of the gate, the concavity is gradually reduced with the formation of the subsequent film layers in the thin film transistor, and since the concavity is not at the edge of other layers, the probability of electric leakage is not produced owing to the concavity. Therefore, compared with the gate in the prior art, the gate in this embodiment may effectively solve the problem of electric leakage caused by the flaw at the sudden change position of the patent in the prior art. Similarly, compared with the source and the drain in the prior art, the source and the drain in this embodiment may effectively solve the problem of electric leakage caused by the flaw at the sudden change position of the pattern in the prior art.

Moreover, the gate preformed layer and the gate are formed by adopting the same mask, the source/drain preformed layer and the source/drain are formed by adopting the same mask, and the corresponding gate preformed layer or the source/drain preformed layer is formed by increasing one exposure and development process without increasing the quantity of masks, so that the above-mentioned solution may achieve the effect of effectively preventing connection between metal electrodes in the thin film transistor.

### Second Embodiment

This embodiment differs from the first embodiment in that, the thin film transistor in this embodiment has a top-gate structure.

In this embodiment, the thin film transistor has a top-gate structure, namely the source and the drain are provided on the substrate, and the gate is provided above the source and the drain. Specifically, the source and the drain, the active layer, the gate insulation layer and the gate are sequentially provided on the substrate. According to different specific forming processes of the gate, the source and the drain, referring to the first embodiment, the thin film transistor in this embodiment specifically includes the following three structures.

As shown in FIG. 8, in the thin film transistor, the source/drain preformed layer 9, the source 7 and the drain 8 are formed on the substrate 1, a source embedded groove is formed in a region, for forming the source, of the source/drain preformed layer 9, a drain embedded groove is formed in a region, for forming the drain, of the source/drain preformed layer 9, the source 7 is provided in the source embedded groove, and the drain 8 is provided in the drain embedded groove. The active layer 5, the gate insulation layer 4 and the gate 2 are sequentially provided above the source 7 and the drain 8.

In addition, in the thin film transistor, the source 7 and the drain 8 are formed on the substrate 1, the active layer 5 and the gate insulation layer 4 are sequentially provided above the source 7 and the drain 8. A gate embedded groove is formed in a region, for forming the gate, of the gate preformed layer 3, and the gate 2 is provided in the gate embedded groove.

In addition, in the thin film transistor, the source/drain preformed layer 9, the source 7 and the drain 8 are formed on the substrate 1, a source embedded groove is formed in a region, for forming the source, of the source/drain preformed layer 9, a drain embedded groove is formed in a region, for forming the drain, of the source/drain preformed layer 9, the source 7 is provided in the source embedded groove, and the drain 8 is provided in the drain embedded groove. The active layer 5 and the gate insulation layer 4 are sequentially provided above the source 7 and the drain 8. A gate embedded groove is formed in a region, for forming the gate, of the gate preformed layer 3, and the gate 2 is provided in the gate embedded groove.

In the above-mentioned structure of the thin film transistor, the gate preformed layer 3 and the source/drain preformed layer 9 are both made of inorganic material, which includes silicon nitride, silicon oxide or silicon oxynitride. The gate 2 may have a thickness the same as the gate preformed layer 3, and the source 7 and the drain 8 may have thicknesses the same as the source/drain preformed layer 9.

The material of each film layer in the thin film transistor of this embodiment is the same as that of the first embodiment, and for the specific manufacturing method, reference may be made to the first embodiment, which is not repeated herein.

### Third Embodiment

This embodiment provides an array substrate, comprising the thin film transistor of the first embodiment.

The array substrate of this embodiment comprises gate lines, data lines and thin film transistors provided in pixel areas formed by the gate lines and the data lines intersecting with each other in different planes, the thin film transistors are the bottom-gate thin film transistors in the first embodiment.

In this embodiment, the gate preformed layer may also extend to regions of the pixel areas other than the regions corresponding to the thin film transistors, and the gate lines are provided in the same layer as the gates and electrically connected with the gates. Moreover, the source/drain preformed layer may also extend to regions of the pixel areas other than the regions corresponding to the thin film transistors, and the data lines are provided in the same layer as the sources and electrically connected with the sources.

Specifically, in the array substrate of this embodiment, gate line embedded grooves are formed in regions, for forming the gate lines, of the gate preformed layer, and the gate lines are provided in the gate line embedded grooves. Moreover, data line embedded grooves are formed in regions, for forming the data lines, of the source/drain preformed layer, and the data lines are provided in the data line embedded grooves. The gate line has a thickness the same as the gate, and the data line has a thickness the same as the source.

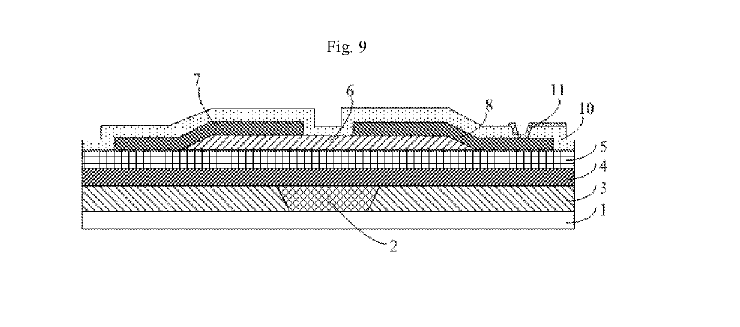

As shown in FIG. 9, the array substrate in this embodiment comprises the above-mentioned thin film transistor and further comprises a passivation layer 10 and a pixel electrode 11, the passivation layer 10 is provided above the source 7 and the drain 8, a via hole is formed in a region, corresponding to the drain 8, of the passivation layer 10, and the passivation layer 10 is made of silicon oxide, silicon nitride, hafnium oxide or aluminum oxide.

The pixel electrode 11 is provided above the passivation layer 10, the drain 8 is connected with the pixel electrode 11 via the via hole, and the pixel electrode 11 is made of indium gallium zinc oxide, indium zinc oxide, indium tin oxide or indium gallium tin oxide.

It should be noted that, the above-mentioned array substrate provided with the pixel electrode may be used for forming a liquid crystal display of TN (Twisted Nematic) mode or VA (Vertical Alignment) mode. Alternatively, a common electrode is subsequently provided on the array substrate so as to form a liquid crystal display of ADS (Advanced Super Dimension Switch) mode. Alternatively, a metal anode of an OLED (Organic Light-Emitting Diode) is formed in a region for forming the pixel electrode in the array substrate so as to form an AMOLED (Active Matrix Organic Light Emission Display).

Accordingly, a manufacturing method of the above-mentioned array substrate comprises the manufacturing method of the thin film transistor in the first embodiment, and may further comprise a step of extending the gate preformed layer to other regions of the pixel areas outside the regions corresponding to the thin film transistors, so that the gate lines are formed in the same layer as the gates and electrically connected with the gates; or may further comprise a step of extending the source/drain preformed layer to other regions of the pixel areas outside the regions corresponding to the thin film transistors, so that the data lines are formed in the same layer as the sources and electrically connected with the sources.

In brief, gate line embedded grooves are formed in regions, for forming the gate lines, of the gate preformed layer, and the gate lines are formed in the gate line embedded grooves. Moreover, data line embedded grooves are formed in regions, for forming the data lines, of the source/drain preformed layer, and the data lines are formed in the data line embedded grooves. The gate line has a thickness the same as the gate, and the data line has a thickness the same as the source.

Specifically, when the thin film transistor has been manufactured in the first embodiment and the gate scan lines and the data lines are preformed, the method further comprises following steps S5 and S6.

Step S5, forming a pattern comprising the passivation layer 10 and the via hole above the source 7 and the drain 8.

In this step, a passivation layer film (PVX) is formed on the substrate 1 subjected to the step S4, a pattern comprising the passivation layer 10 may be formed above the source 7 and the drain 8 by using a normal mask via one patterning process, and a pattern comprising the via hole is formed in the passivation layer 10 by an etching method. The passivation layer film is formed by a method of deposition, sputtering or thermal evaporation.

Step S6, forming a pattern comprising the pixel electrode 11 on the passivation layer 10, the drain 8 is connected with the pixel electrode 11 via the via hole.

In this step, a transparent conductive film is formed on the substrate 1 subjected to the step S5, the pattern comprising the pixel electrode 11 is formed above the passivation layer 10 by using a normal mask via one patterning process, and the drain 8 is connected with the pixel electrode 11 via the via hole. The transparent conductive film is formed by a method of deposition, sputtering or thermal evaporation.

In the array substrate of this embodiment, the gate lines and the gates are simultaneously formed, the data lines and the sources/drains are simultaneously formed, the gate line embedded grooves and the gate embedded grooves are simultaneously formed, and the data line embedded grooves, the source embedded grooves and the drain embedded grooves are simultaneously formed, so that the effect of effectively preventing electric leakage may be achieved without increasing the quantity of masks.

### Fourth Embodiment

This embodiment provides an array substrate, comprising the thin film transistor in the second embodiment.

The array substrate of this embodiment comprises gate lines, data lines and thin film transistors provided in pixel areas formed by the gate lines and the data lines intersecting with each other in different planes, the thin film transistors are the bottom-gate thin film transistors in the second embodiment.

In this embodiment, the gate preformed layer may also extend to regions of the pixel areas other than the regions corresponding to the thin film transistors, and the gate lines are provided in the same layer as the gates and electrically connected with the gates. Moreover, the source/drain preformed layer may also extend to regions of the pixel areas other than the regions corresponding to the thin film transistors, and the data lines are provided in the same layer as the sources and electrically connected with the sources.

Specifically, in the array substrate of this embodiment, gate line embedded grooves are formed in regions, for forming the gate lines, of the gate preformed layer, and the gate lines are provided in the gate line embedded grooves. Moreover, data line embedded grooves are formed in regions, for forming the data lines, of the source/drain preformed layer, and the data lines are provided in the data line embedded grooves. The gate line has a thickness the same as the gate, and the data line has a thickness the same as the source.

Other structures of the array substrate of this embodiment are the same as those of the third embodiment, and for the specific manufacturing method, reference may be made to the third embodiment, which is not repeated herein.

### Fifth Embodiment

This embodiment provides a display device, comprising the array substrate of the third or fourth embodiment. The display device may be any product or component with a display function, such as a liquid crystal panel, electronic paper, an OLED (organic light-emitting diode) panel, a mobile phone, a tablet computer, a television, a display, a notebook computer, a digital photo frame or a navigator.

In this embodiment, the adopted array substrate has the effect of effectively preventing electric leakage, so that the display device has high stability and high display quality.

In the manufacturing process of the thin film transistor of the present invention, inorganic material is first formed on a substrate, and a groove corresponding to a pattern of a gate is formed through exposure, development and etching; then a gate is formed, and the thickness of the gate is consistent with the depth of the groove, so that a complete pattern where gate metal material is filled into the groove is formed; and other film layers of the thin film transistor are then formed. Moreover, the source and the drain may have a structure similar to the gate. This structure may effectively reduce the negative effects caused by etching defects or flaws of the gate or the source and the drain at the slope, effectively solve the technical problem that unexpected flaws occur in the gate metal layer film or the source/drain metal layer film during depositing and etching, fundamentally avoid the probability of discontinuity of the subsequent layers and improve the quality of the display device.

Accordingly, in the array substrate adopting the above-mentioned thin film transistor in the present invention, the gate lines connected with the gates and the data lines connected with the sources are also formed in the inorganic material layer, so that the edge slope area of each conductive film layer is reduced with the increment of the subsequent film layers, negative effects caused by the flaws of the gate lines and the data lines at the slope may be effectively reduced, and thus it is possible to obtain a perfect display screen of the display device under the general background that pixels are gradually refined.

The structure of the thin film transistor and the corresponding manufacturing method provided by the present invention may be popularized to various structures of semiconductor device with multiple film layers and manufacturing methods thereof. The core of the manufacturing method lies in that a groove of a pattern of the semiconductor device to be formed is first formed by using other material and then the material for forming the pattern of the semiconductor device is filled into the groove, and by adopting the manufacturing method, masks do not need to be increased, the influence of incomplete slopes of former film layers on the subsequent film layers may be reduced and the probability of electric leakage in the semiconductor device may be effectively avoided.

It could be understood that, the above embodiments are merely exemplary embodiments adopted for describing the principle of the present invention, rather than limiting the present invention. Various modifications and improvements may be made for those of ordinary skill in the art without departing from the spirit and essence of the present invention, and these modifications and improvements are regarded within the protection scope of the present invention.

1-20. (canceled)

21. A thin film transistor, comprising a substrate, and a gate, an active layer, a source, a drain and an insulation layer which are provided on the substrate, the source and the drain being provided in the same layer, and the insulation layer being provided between the gate and the source and drain, wherein
a gate preformed layer is provided in the same layer as the gate, and the gate is formed in the gate preformed layer; and/or
a source/drain preformed layer is provided in the same layer as the source and the drain, and the source and the drain are formed in the source/drain preformed layer.

22. The thin film transistor of claim 21, wherein the gate is provided on the substrate, and the source and the drain are provided above the gate;
a gate embedded groove is formed in a region of the gate preformed layer for forming the gate, and the gate is provided in the gate embedded groove; and/or
a source embedded groove is formed in a region of the source/drain preformed layer for forming the source, a drain embedded groove is formed in a region of the source/drain preformed layer for forming the drain, the source is provided in the source embedded groove, and the drain is provided in the drain embedded groove.

23. The thin film transistor of claim 21, wherein the source and the drain are provided on the substrate, and the gate is provided above the source and the drain;
a source embedded groove is formed in a region of the source/drain preformed layer for forming the source, a drain embedded groove is formed in a region of the source/drain preformed layer for forming the drain, the source is provided in the source embedded groove, and the drain is provided in the drain embedded groove; and/or
a gate embedded groove is formed in a region of the gate preformed layer for forming the gate, and the gate is provided in the gate embedded groove.

24. The thin film transistor of claim 22, wherein the gate preformed layer and the source/drain preformed layer are both made of inorganic material, and the inorganic material comprises silicon nitride, silicon oxide or silicon oxynitride.

25. The thin film transistor of claim 23, wherein the gate preformed layer and the source/drain preformed layer are both made of inorganic material, and the inorganic material comprises silicon nitride, silicon oxide or silicon oxynitride.

26. The thin film transistor of claim 24, wherein the gate has a thickness the same as the gate preformed layer, and the source and the drain have thicknesses the same as the source/drain preformed layer.

27. The thin film transistor of claim 25, wherein the gate has a thickness the same as the gate preformed layer, and the source and the drain have thicknesses the same as the source/drain preformed layer.

28. The thin film transistor of claim 21, wherein the active layer is provided between the insulation layer and the source and drain, the active layer is at least partially superposed with the source and the drain respectively in a positive projection direction, and the active layer is made of amorphous silicon material, or is made of indium gallium zinc oxide, indium zinc oxide, indium tin oxide or indium gallium tin oxide.

29. A display device, comprising an array substrate, the array substrate comprising gate lines, data lines and thin film transistors provided in pixel areas formed by the gate lines and the data lines intersecting with each other in different planes, wherein the thin film transistor comprises a substrate, and a gate, an active layer, a source, a drain and an insulation layer which are provided on the substrate, the source and the drain is provided in the same layer, and the insulation layer is provided between the gate and the source and drain, wherein
a gate preformed layer is provided in the same layer as the gate, and the gate is formed in the gate preformed layer; and/or
a source/drain preformed layer is provided in the same layer as the source and the drain, and the source and the drain are formed in the source/drain preformed layer.

30. The display device of claim 29, wherein the gate preformed layer also extends to other regions of the pixel areas outside the regions corresponding to the thin film transistors, and the gate lines are provided in the same layer as the gates and electrically connected with the gates; and/or
the source/drain preformed layer also extends to other regions of the pixel areas outside the regions corresponding to the thin film transistors, and the data lines are provided in the same layer as the sources and electrically connected with the sources.

31. The display device of claim 30, wherein gate line embedded grooves are formed in regions of the gate preformed layer for forming the gate lines, and the gate lines are provided in the gate line embedded grooves; and/or
data line embedded grooves are formed in regions of the source/drain preformed layer for forming the data lines, and the data lines are provided in the data line embedded grooves.

32. The display device of claim 31, wherein the gate line has a thickness the same as the gate, and the data line has a thickness the same as the sources.

33. The display device of claim 29, wherein
a gate embedded groove is formed in a region of the gate preformed layer for forming the gate, and the gate is provided in the gate embedded groove; and/or
a source embedded groove is formed in a region of the source/drain preformed layer for forming the source, a drain embedded groove is formed in a region of the source/drain preformed layer for forming the drain, the source is provided in the source embedded groove, and the drain is provided in the drain embedded groove.

34. The display device of claim 33, wherein the gate preformed layer and the source/drain preformed layer are both made of inorganic material, and the inorganic material comprises silicon nitride, silicon oxide or silicon oxynitride.

35. The display device of claim 33, wherein the gate has a thickness the same as the gate preformed layer, and the source and the drain have thicknesses the same as the source/drain preformed layer.

36. A manufacturing method of a thin film transistor, comprising steps of forming a gate, an active layer, a source and a drain, and a gate insulation layer on a substrate, the gate insulating layer being provided between the gate and the source and drain, wherein the manufacturing method further comprises steps of:
forming a gate preformed layer in the same layer as the gate, and forming the gate in the gate preformed layer; and/or
forming a source/drain preformed layer in the same layer as the source and the drain, and forming the source and the drain in the source/drain preformed layer.

37. The manufacturing method of claim 36, wherein before the gate is formed, a pattern comprising the gate preformed layer and a gate embedded groove provided in the gate preformed layer is first formed; then a pattern comprising the gate is formed in the gate embedded groove; and/or
before the source and the drain are formed, a pattern comprising the source/drain preformed layer as well as a source embedded groove and a drain embedded groove provided in the source/drain preformed layer is first formed; then a pattern comprising the source is formed in the source embedded groove, and a pattern comprising the drain is formed in the drain embedded groove.

38. The manufacturing method of claim 37, wherein a pattern comprising the gate preformed layer and the gate is formed by a patterning process, and the gate preformed layer and the gate are formed by adopting the same mask; or, a pattern comprising the gate preformed layer is formed by a patterning process, and the gate is formed in the gate embedded groove of the gate preformed layer by a melt perfusion manner; and/or
a pattern comprising the source/drain preformed layer as well as the source and the drain is formed by a patterning process, and the source/drain preformed layer as well as the source and the drain are formed by adopting the same mask; or, a pattern comprising the source/drain preformed layer is formed by a patterning process, and the source and the drain are respectively formed in the source embedded groove and the drain embedded groove of the source/drain preformed layer by a melt perfusion manner.

39. The manufacturing method of claim 38, wherein the gate preformed layer and the source/drain preformed layer are made of inorganic material which comprises silicon nitride, silicon oxide or silicon oxynitride.

40. The manufacturing method of claim 39, wherein the gate has a thickness the same as the gate preformed layer, and the source and the drain have thicknesses the same as the source/drain preformed layer.
